(19) United States
(12) Patent Application Publication
(10) Pub. No.: US 2026/0075852 A1
(43) Pub. Date: Mar. 12, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Ya-Jyuan Hung, Kaohsiung City (TW); Fu-Yu Tsai, Tainan city (TW); Bin-Siang Tsai, Changhua County (TW)

(73) Assignee: UNITED MICROELECTRONICS CORP., Hsin-Chu City (TW)

(21) Appl. No.: 18/912,549

(22) Filed: Oct. 10, 2024

(30) Foreign Application Priority Data
Sep. 9, 2024 (TW) 113134065

(51) Int. Cl. H10D 1/68

(52) U.S. Cl. CPC H10D 1/716

(57) ABSTRACT

A semiconductor device includes a bottom electrode, a protective layer, an insulating layer, a top electrode, a first contact structure and a second contact structure. The bottom electrode includes a first step structure. The first step structure includes a first step surface and a second step surface lower than the first step surface. The protective layer is disposed on the second step surface. The insulating layer is disposed on the first step surface. The top electrode is disposed on the insulating layer. The first contact structure is electrically connected with the bottom electrode. The second contact structure is electrically connected with the top electrode.

### BACKGROUND OF THE INVENTION

### 1. Field of the Invention

The present disclosure relates to the field of semiconductor devices, and more particularly, to a semiconductor device including a metal-insulator-metal (MIM) structure and a method for fabricating the same.

### 2. Description of the Prior Art

In the field of semiconductors, MIM structures are widely applied in semiconductor devices. For example, the MIM structure can form a capacitor. The capacitor with the MIM structure has a lower resistance and a smaller parasitic capacitance, and has no problem of the shift of induced voltage in the depletion region. Therefore, the MIM structure is one of the main structures of current capacitors. With the popularization of the application of the MIM structures, how to improve the semiconductor devices including the MIM structures and the method fabricating the same has become the goal of relevant industry.

### SUMMARY OF THE INVENTION

According to an embodiment of the present disclosure, a semiconductor device includes a bottom electrode, a protective layer, an insulating layer, a top electrode, a first contact structure and a second contact structure. The bottom electrode includes a first step structure. The first step structure includes a first step surface and a second step surface lower than the first step surface. The protective layer is disposed on the second step surface. The insulating layer is disposed on the first step surface. The top electrode is disposed on the insulating layer. The first contact structure is electrically connected with the bottom electrode. The second contact structure is electrically connected with the top electrode.

According to another embodiment of the present disclosure, a method for fabricating a semiconductor device includes steps as follows. A bottom electrode is formed. The bottom electrode includes a first step structure, and the first step structure includes a first step surface and a second step surface lower than the first step surface. A protective layer is formed on the second step surface. An insulating layer is formed on the first step surface. A top electrode is formed on the insulating layer. A first contact structure electrically connected with the bottom electrode is formed. A second contact structure electrically connected with the top electrode is formed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6 and FIG. 7 are schematic cross-sectional views showing steps for fabricating a semiconductor device according to an embodiment of the present disclosure.

FIG. 8, FIG. 9, FIG. 10, FIG. 11 and FIG. 12 are schematic cross-sectional views showing steps for fabricating a semiconductor device according to another embodiment of the present disclosure.

FIG. 13 is a schematic cross-sectional view showing a step for fabricating a semiconductor device according to yet another embodiment of the present disclosure.

FIG. 14 is a schematic cross-sectional view showing a semiconductor device according to yet another embodiment of the present disclosure.

FIG. 15 is a schematic cross-sectional view showing a semiconductor device according to yet another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

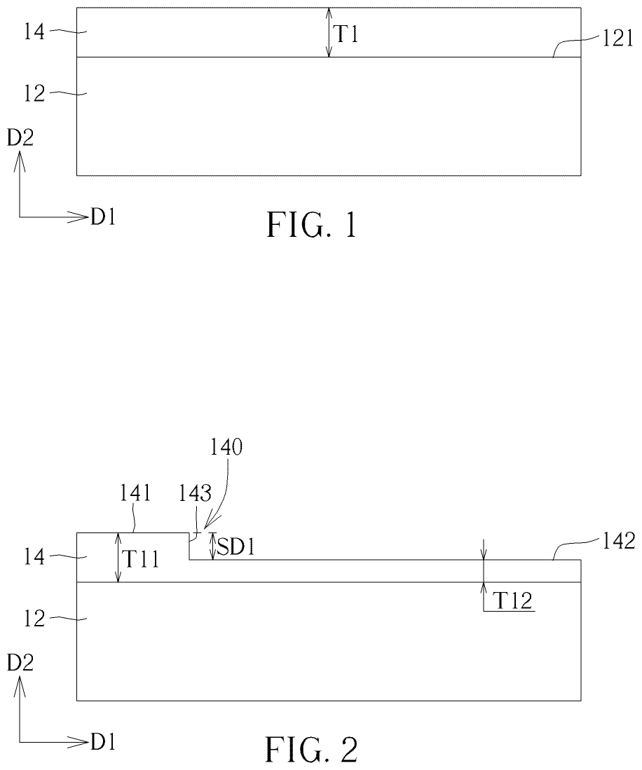

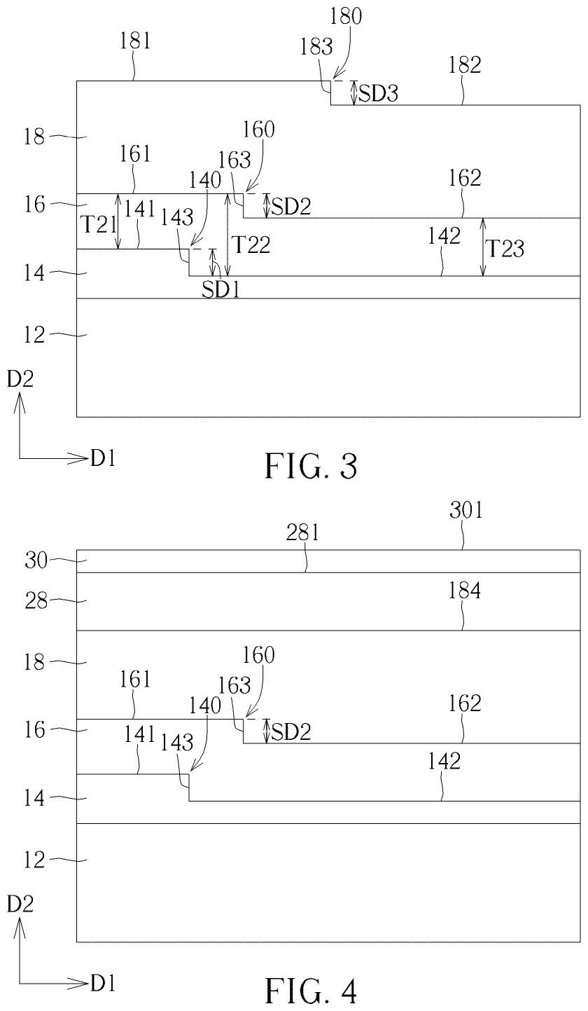

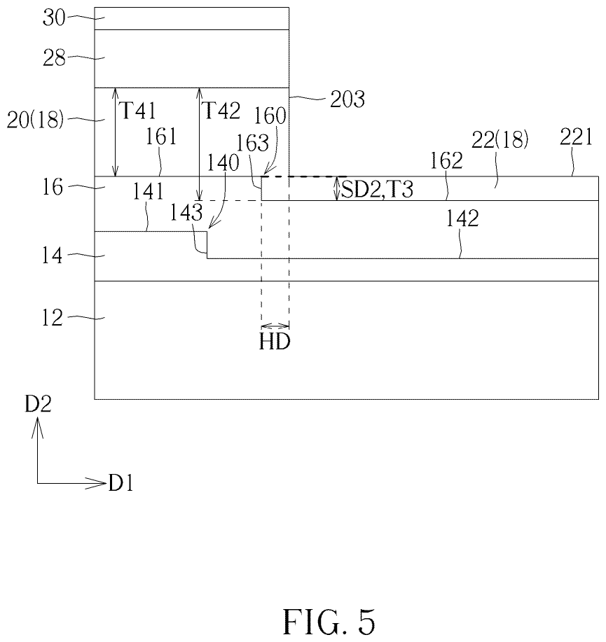

Please refer to FIG. 1 to FIG. 7, which are schematic cross-sectional views showing steps for fabricating a semiconductor device 10 according to an embodiment of the present disclosure. As shown in FIG. 1, a dielectric layer 14 may be firstly formed on a substrate 12. At this stage, the dielectric layer 14 has a uniform thickness T1. The thickness T1 may be, for example, 500 angstroms to 1000 angstroms, but not limited thereto. In the present disclosure, a thickness of an element may refer to a length of the element in the vertical direction D2. The vertical direction D2, for example, may be perpendicular to the top surface 121 of the substrate 12. The substrate 12 may include a silicon substrate, an epitaxial silicon substrate, a silicon carbide substrate or a silicon on insulator (SOI) substrate. Although not shown in the drawings, semiconductor elements, such as active elements and/or passive elements, may be formed in the substrate 12 and the dielectric layer 14 according to actual needs. The active elements and the passive elements may be, for example, transistors, diodes, capacitors, inductors and resistors, but not limited thereto. In addition, other film layers and semiconductor elements may be formed between the substrate 12 and the dielectric layer 14 according to actual needs.

Next, as shown in FIG. 2, semiconductor processes, such as photolithography and etching processes, may be performed to remove a portion of the dielectric layer 14 to form a step structure 140 on the dielectric layer 14. The step structure 140 may include a first step surface 141, a connecting surface 143 and a second step surface 142 sequentially connected. The second step surface 142 is lower than the first step surface 141, and there is a step difference SD1 between the first step surface 141 and the second step surface 142 in the vertical direction D2. Specifically, the portion of the dielectric layer 14 located on the second step surface 142 is removed to form the step structure 140, so that the dielectric layer 14 has different thicknesses T11 and T12. The portion of the dielectric layer 14 located below the first step surface 141 has the thickness T11, and he portion of the dielectric layer 14 located below the second step surface 142 has the thickness T12. The thickness T11 is substantially equal to the thickness T1 (see FIG. 1). The thickness T11 is greater than the thickness T12, and the thickness T11 is equal to the sum of the thickness T12 and step difference SD1.

Next, as shown in FIG. 3, a bottom electrode 16 is formed on the dielectric layer 14, wherein the bottom electrode 16 conformally covers the dielectric layer 14 and thus includes a step structure 160. The step structure 160 may include a first step surface 161, a connecting surface 163 and a second step surface 162 sequentially connected. The second step surface 162 is lower than the first step surface 161, and there is a step difference SD2 between the first step surface 161 and the second step surface 162 in the vertical direction D2. The step difference SD2 is substantially equal to the step difference SD1. The first step surface 161 is disposed above the first step surface 141, and the second step surface 162 is disposed above the second step surface 142. The bottom electrode 16 has different thicknesses T21, T22, and T23. The portion of the bottom electrode 16 between the first step surface 141 and the first step surface 161 has the thickness T21. The portion of the bottom electrode 16 between the second step surface 142 and the first step surface 161 has the thickness T22. The portion of the bottom electrode 16 between the second step surface 142 and the second step surface 162 has the thickness T23. The thickness T21 is substantially equal to the thickness T23. The thickness T22 is greater than the thickness T21 and the thickness T23. In addition, the thickness T22 is equal to the sum of the thickness T21 and the step difference SD2 or the sum of the thickness T23 and the step difference SD2. According to an embodiment of the present disclosure, the thickness T21 may be 400 angstroms to 3000 angstroms, but not limited thereto.

As shown in FIG. 3, an insulating layer 18 is formed on the bottom electrode 16, wherein the insulating layer 18 conformally covers the bottom electrode 16 and thus includes a step structure 180. The step structure 180 may include a first step surface 181, a connecting surface 183 and a second step surface 182 sequentially connected. The second step surface 182 is lower than the first step surface 181, and there is a step difference SD3 between the first step surface 181 and the second step surface 182 in the vertical direction D2. The step difference SD3 is substantially equal to the step difference SD2.

Next, as shown in FIG. 4, a planarization process, such as a chemical mechanical polishing (CMP) process, may be performed to remove a portion of the insulating layer 18, so that the insulating layer 18 has a flat top surface 184 and no longer has the step structure 180. Before performing the planarization process, a sacrificial insulating layer (not shown) may be formed on the insulating layer 18. With the sacrificial insulating layer, the thickness of the entire insulating layer (i.e., the sum of the thicknesses of the insulating layer 18 and the sacrificial insulating layer) can be increased, which is beneficial to improve the flatness of the top surface 184. The sacrificial insulating layer may include an oxide such as silicon dioxide, but not limited thereto.

Next, a top electrode 28 and a dielectric layer 30 are sequentially formed on the insulating layer 18. The top electrode 28 follows the surface morphology of the insulating layer 18 and thus has a flat top surface 281, and the dielectric layer 30 follows the surface morphology of the top electrode 28 and thus has a flat top surface 301.

Next, as shown in FIG. 5, the size of the top electrode 28 is defined, in which a portion of the dielectric layer 30, a portion of the top electrode 28 and a portion of the insulating layer 18 may be removed by semiconductor processes, such as one or more photolithography and etching processes. In the remaining portion of the insulating layer 18, the portion covered by the top electrode 28 is the insulating layer 20, and the portion exposed from the top electrode 28 is the protective layer 22. That is, in this step, the protective layer 22 can be formed on the second step surface 162, the insulating layer 20 can be formed on the first step surface 161, and the top electrode 28 can be formed on the insulating layer 20. The insulating layer 20 is located between the top electrode 28 and the bottom electrode 16. The bottom electrode 16, the insulating layer 20 and the top electrode 28 can together form an MIM structure. The MIM structure can serve as a capacitor. The insulating layer 20 has different thicknesses T41 and T42. The portion of the insulating layer 20 between the first step surface 161 and the top electrode 28 has the thickness T41. The portion of the insulating layer 20 between the second step surface 162 and the top electrode 28 has the thickness T42. The capacitance value provided by the MIM structure is mainly determined by the thickness T41. Therefore, unless otherwise specified below, the thickness of the insulating layer 20 refers to the thickness T41. The protective layer 22 is disposed on the second step surface 162 of the bottom electrode 16. With the protective layer 22, it can prevent the etchant used in the etching process of defining the top electrode 28 from contacting the bottom electrode 16. Thereby, it can prevent the bottom electrode 16 from being damaged when defining the top electrode 28. For example, the second step surface 162 of the bottom electrode 16 can be prevented from becoming rough.

When the bottom electrode 16 is not disposed with the protective layer 22, it requires to accurately control the etching depth when defining the top electrode 28. Excessive etching may damage the bottom electrode 16, which may affect the properties and the yield the semiconductor device 10 formed later. In other words, with the protective layer 22, the process window for defining the top electrode 28 can be enlarged, which is beneficial to maintain the performance of the semiconductor device 10 (see FIG. 7) and/or enhance the yield of the semiconductor device 10. In addition, in the present disclosure, with the bottom electrode 16 including the step structure 160, it can provide the space for disposing the protective layer 22 without increasing the thickness T41 of the insulating layer 20. That is, with the bottom electrode 16 including the step structure 160, the protective layer 22 can be provided to protect the bottom electrode 16 without sacrificing the capacitance value provided by the MIM structure.

In this embodiment, the insulating layer 20 and the protective layer 22 are formed by removing a portion of the insulating layer 18. Therefore, the insulating layer 20 and the protective layer 22 are formed in the same step, and the insulating layer 20 and the protective layer 22 include the same material. Thereby, the fabricating process can be simplified.

The protective layer 22 has a thickness T3, and the thickness T3 of the protective layer 22 may be different from the thickness T41 of the insulating layer 20. According to an embodiment of the present disclosure, a ratio of the thickness T41 of the insulating layer 20 to the thickness T3 of the protective layer 22 may be greater than or equal to 4. For example, the thickness T41 of the insulating layer 20 may be 200 angstroms to 300 angstroms, or may be 225 angstroms to 265 angstroms. The thickness T3 of the protective layer 22 may be less than or equal to 75 angstroms, or may be less than or equal to 60 angstroms, or may be 10 angstroms to 50 angstroms.

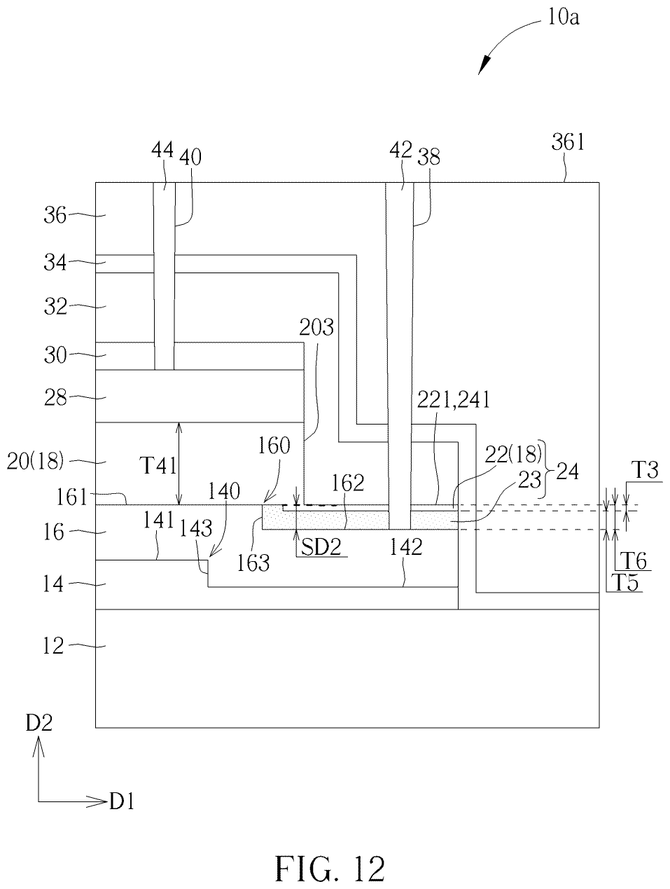

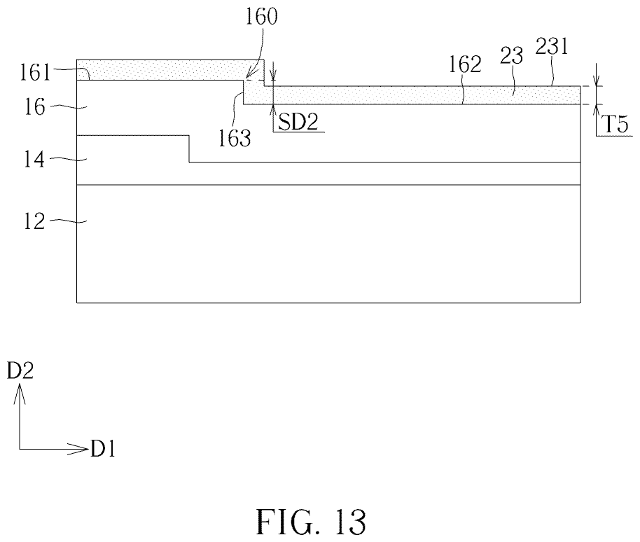

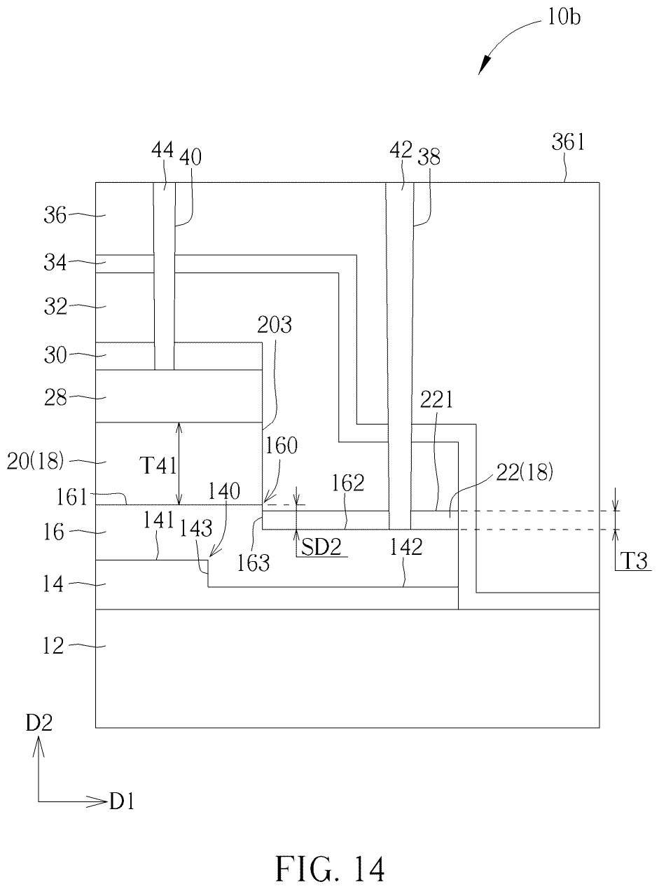

In this embodiment, the top surface 221 of the protective layer 22 is aligned with the first step surface 161, and the thickness T3 of the protective layer 22 is equal to the step difference SD2, but not limited thereto. In other embodiments, the top surface 221 of the protective layer 22 may be lower than the first step surface 161 (that is, the thickness T3 of the protective layer 22 may be less than the step difference SD2), which can also achieve the effect of protecting the bottom electrode 16 without sacrificing the the capacitance value provided by the MIM structure. In this embodiment, the length (not labeled) of the insulating layer 20 in the horizontal direction D1 is greater than the length (not labeled) of the first step surface 161 in the horizontal direction D1. There is a spacing distance HD between the side surface 203 of the insulating layer 20 and the connecting surface 163 in the horizontal direction D1, and the protective layer 22 overlaps the insulating layer 20 in the vertical direction D2, but not limited thereto. In other embodiments, the length (not labeled) of the insulating layer 20 in the horizontal direction D1 may be equal to the length (not labeled) of the first step surface 161 in the horizontal direction D1. In this case, the side surface 203 of the insulating layer 20 is aligned with the connecting surface 163, the spacing distance HD is equal to 0, and the protective layer 22 does not overlap the insulating layer 20 in the vertical direction D2, which may refer to the relevant description of FIG. 14.

Next, as shown in FIG. 6, a dielectric layer 32 may be blanketly deposited on the substrate 12 to cover the dielectric layer 30 and the protective layer 22. Next, the size of the bottom electrode 16 is defined, in which a portion of the dielectric layer 32, a portion of the protective layer 22, a portion of the bottom electrode 16 and a portion of the dielectric layer 14 may be removed by semiconductor processes, such as one or more photolithography and etching processes. Next, a dielectric layer 34 may be blanketly deposited on the substrate 12 to cover the dielectric layer 32 and the substrate 12.

Next, as shown in FIG. 7, a first contact structure 42 electrically connected with the bottom electrode 16 and a second contact structure 44 electrically connected with the top electrode 28 are formed, which may include as follows. First, a dielectric layer 36 may be blanketly deposited on the substrate 12 to cover the dielectric layer 34, and then a portion of the dielectric layer 36 may be removed through a planarization process, so that the dielectric layer 36 has a flat top surface 361. Next, a plug process is performed, in which a portion of the dielectric layer 36, a portion of the dielectric layer 34, a portion of the dielectric layer 32 and a portion of the protective layer 22 may be removed by semiconductor processes, such as photolithography and etching processes, to form a hole 38 to expose the bottom electrode 16. Moreover, a portion of the dielectric layer 36, a portion of the dielectric layer 34, a portion of the dielectric layer 32 and a portion of the dielectric layer 30 may be removed by further semiconductor processes, such as photolithography and etching processes, to form a hole 40 to expose the top electrode 28. Next, a conductive material is filled into the hole 38 and the hole 40, and then a planarization process is performed to form the first contact structure 42 and the second contact structure 44 in the dielectric layer 36. The first contact structure 42 is electrically connected with the bottom electrode 16, and the second contact structure 44 is electrically connected with the top electrode 28. Thereby, the fabrication of the semiconductor device 10 can be completed.

The material of the dielectric layer 14 may include oxides, such as silicon dioxide or tetraethoxysilane (TEOS), but not limited thereto. The material of the insulating layer 18 may include a high dielectric constant dielectric material such as a dielectric material with a dielectric constant greater than or equal to 4, but not limited thereto. The insulating layer 18 may be a single layer structure or a composite structure formed by multiple film layers. For example, the insulating layer 18 may include a nitride, such as silicon nitride (SiN), silicon carbonitride (SiCN) or a combination thereof, but not limited thereto. Each of the bottom electrode 16 and the top electrode 28 may be a single layer structure or a composite structure formed by multiple film layers. The materials of the bottom electrode 16 and the top electrode 28 may independently include conductive materials, such as copper (Cu), chromium (Cr), titanium (Ti), tungsten (W), gold (Au), aluminum (Al), indium (In), tin (Sn), nickel (Ni), platinum (Pt), silver (Ag), an alloy of the aforementioned materials or a combination thereof, but not limited thereto. The materials of the dielectric layers 30, 32, and 34 may independently include a nitride, such as silicon nitride (SiN) and silicon carbonitride (SiCN), but not limited thereto. The material of the dielectric layer 36 may include an oxide, such as silicon dioxide or tetraethoxysilane, but not limited thereto. The conductive materials of the first contact structure 42 and the second contact structure 44 may be the same or different, and may independently include a barrier layer (not shown) and a metal layer (not shown). The material of the barrier layer may include titanium, tantalum, titanium nitride, tantalum nitride, nitrogen or a combination thereof. The material of the metal layer may include aluminum, titanium, tantalum, tungsten, niobium, molybdenum, copper or a combination thereof, but not limited thereto.

Please refer to FIG. 7, which is a schematic cross-sectional view showing the semiconductor device 10 according to an embodiment of the present disclosure. The semiconductor device 10 includes the bottom electrode 16, a protective layer 22, an insulating layer 20, the top electrode 28, the first contact structure 42 and the second contact structure 44, and may optionally include the dielectric layers 14, 30, 32, 34 and 36. The bottom electrode 16 includes a step structure 160. The step structure 160 includes the first step surface 161 and the second step surface 162. The second step surface 162 is lower than the first step surface 161. The protective layer 22 is disposed on the second step surface 162. The insulating layer 20 is disposed on the first step surface 161. The top electrode 28 is disposed on the insulating layer 20. The first contact structure 42 is electrically connected with the bottom electrode 16, and the second contact structure 44 is electrically connected with the top electrode 28. The dielectric layer 14 is disposed below the bottom electrode 16, wherein the dielectric layer 14 includes the step structure 140. The step structure 140 includes the first step surface 141 and the second step surface 142. The second step surface 142 is lower than the first step surface 141. The first step surface 161 is disposed above the first step surface 141, and the second step surface 162 is disposed above the second step surface 142. The dielectric layer 14 has different thicknesses T11 and T12 (see FIG. 2).

In FIG. 7, the top surface 221 of the protective layer 22 may be aligned with the first step surface 161. The thickness T3 of the protective layer 22 may be different from the thickness T41 of the insulating layer 20. Herein, the thickness T3 is less than the thickness T41. The ratio of the thickness T41 of the insulating layer 20 to the thickness T3 of the protective layer 22 may be greater than or equal to 4. The protective layer 22 and the insulating layer 20 may include the same material. For other details of the semiconductor device 10, references may be made to the above description and are omitted herein.

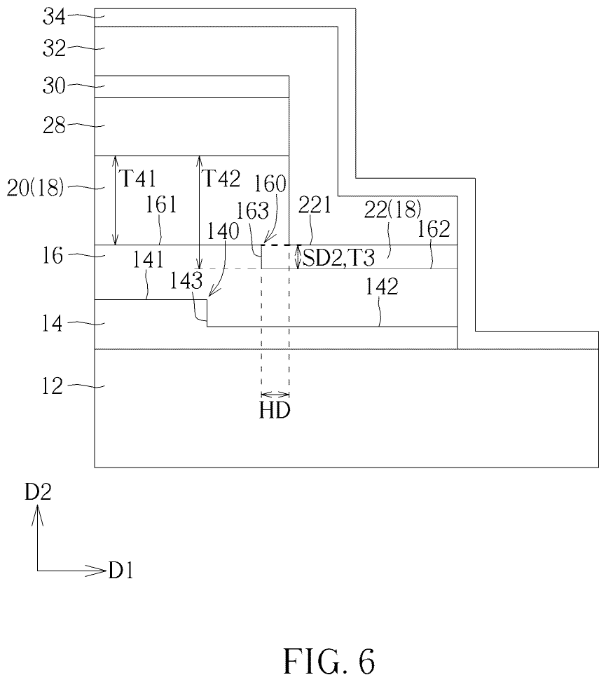

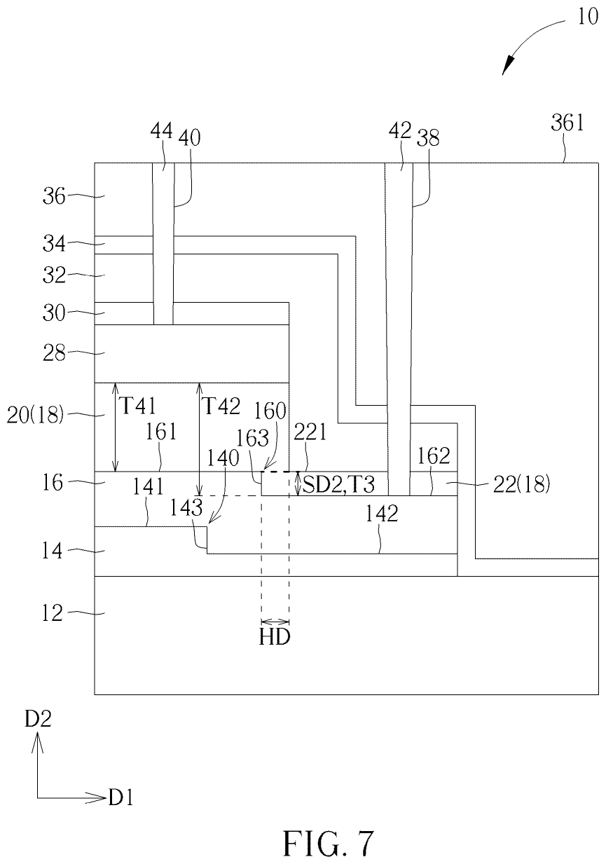

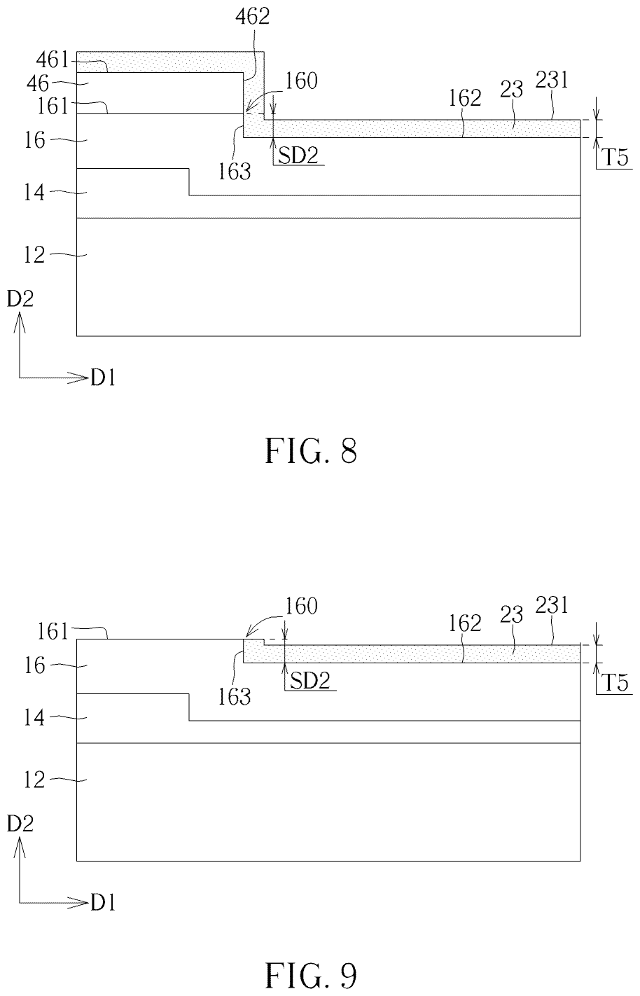

Please refer to FIG. 1, FIG. 2, FIG. 8 to FIG. 12, which are schematic cross-sectional views showing steps for fabricating a semiconductor device 10a according to another embodiment of the present disclosure. As shown in FIG. 1, a dielectric layer 14 may be firstly formed on a substrate 12. Next, as shown in FIG. 2, a portion of the dielectric layer 14 is removed to form a step structure 140 on the dielectric layer 14.

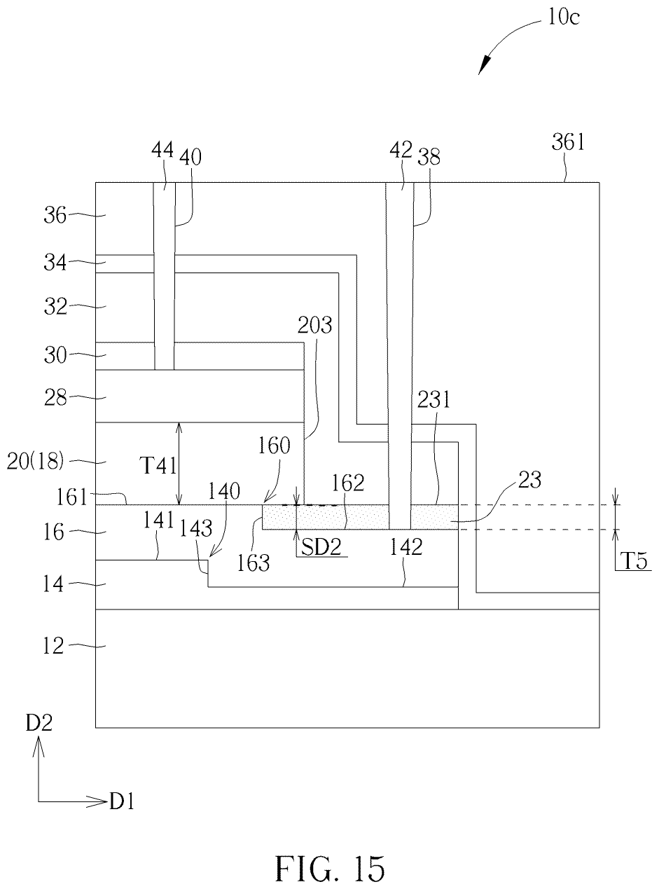

Next, as shown in FIG. 8, a bottom electrode 16 is formed on the dielectric layer 14, wherein the bottom electrode 16 conformally covers the dielectric layer 14 and thus includes a step structure 160. The step structure 160 may include a first step surface 161, a connecting surface 163 and a second step surface 162 sequentially connected. The second step surface 162 is lower than the first step surface 161, and there is a step difference SD2 between the first step surface 161 and the second step surface 162 in the vertical direction D2. Next, a photoresist 46 is formed on the first step surface 161, and a protective layer 23 is blanketly deposited on the substrate 12 to cover the photoresist 46 and the bottom electrode 16. In FIG. 8, the thickness T5 of the protective layer 23 is less than the step difference SD2, but not limited thereto. In other embodiments, the thickness T5 of the protective layer 23 may be equal to the step difference SD2, which may refer to the relevant description of FIG. 15.

Next, as shown in FIG. 9, the photoresist 46 and the portion of the protective layer 23 on the photoresist 46 are removed, and the portion of the protective layer 23 on the second step surface 162 is reserved. For example, a planarization process such as CMP may be performed to remove the protective layer 23 on the top surface 461 of the photoresist 46, and then a solvent is used to dissolve the photoresist 46, so that the protective layer 23 on the side surface 462 of the photoresist 46 is also removed. Alternatively, the photoresist 46 can be a dry film photoresist. The protective layer 23 on the side surface 462 of the photoresist 46 can be removed by peeling the photoresist 46 off. Thereby, the first step surface 161 can be prevented from being scratched or damaged caused by performing a planarization process. However, the present disclosure is not limited thereto. The semiconductor structure shown in FIG. 9 can be obtained by other methods.

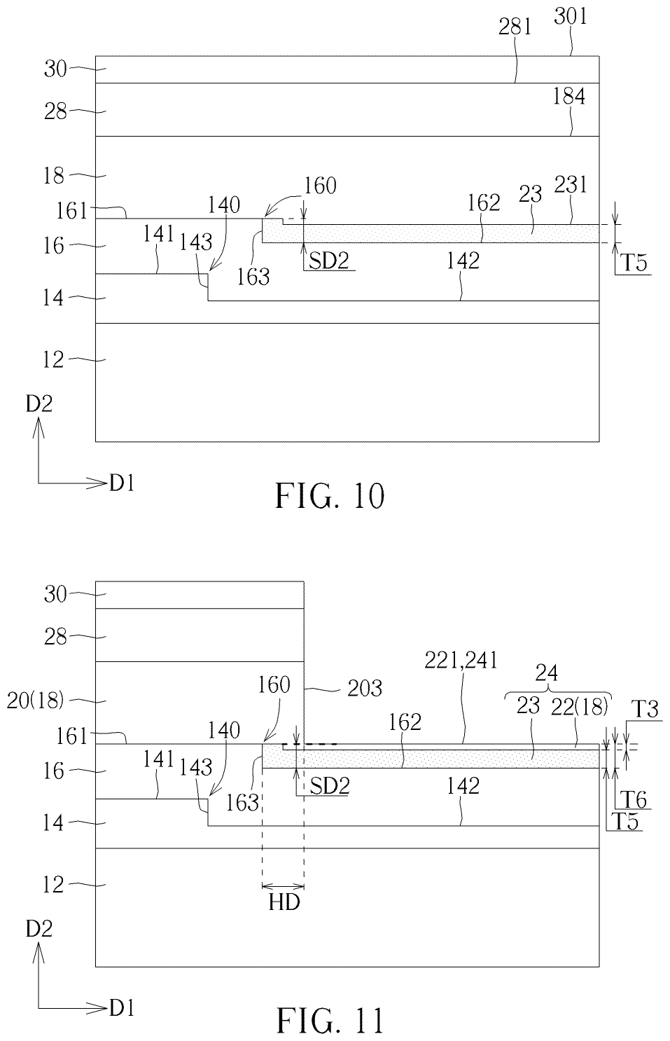

For example, please refer to FIG. 2, FIG. 13 and FIG. 9 at the same time. In FIG. 2, a portion of the dielectric layer 14 is removed to form the step structure 140. Afterward, as shown in FIG. 13, the bottom electrode 16 may be formed on the dielectric layer 14. Next, the step of forming the photoresist 46 in FIG. 8 may be omitted, and the protective layer 23 is blanketly deposited on the substrate 12 to cover the bottom electrode 16. Next, the portion of the protective layer 23 on the first step surface 161 is removed by a planarization process such as CMP, so as to obtain the semiconductor structure in shown in FIG. 9. Thereby, there is no need to form the photoresist 46, which is beneficial to simplify the fabricating process.

Next, as shown in FIG. 10, an insulating layer 18 is formed on the bottom electrode 16, and then a planarization process is performed to remove a portion of the insulating layer 18, so that the insulating layer 18 has a flat top surface 184. Next, a top electrode 28 and a dielectric layer 30 are sequentially formed on the insulating layer 18. The top electrode 28 follows the surface morphology of the insulating layer 18 and thus has a flat top surface 281, and the dielectric layer 30 follows the surface morphology of the top electrode 28 and thus has a flat top surface 301.

Next, as shown in FIG. 11, the size of the top electrode 28 is defined, a portion of the dielectric layer 30, a portion of the top electrode 28 and a portion of the insulating layer 18 may be removed by semiconductor processes, such as one or more photolithography and etching processes. In the remaining portion of the insulating layer 18, the portion of the insulating layer 18 covered by the top electrode 28 is the insulating layer 20, and the portion of the insulating layer 18 exposed from the top electrode 28 is the protective layer 22. The insulating layer 20 is located between the top electrode 28 and the bottom electrode 16. The bottom electrode 16, the insulating layer 20 and the top electrode 28 may together form an MIM structure. The protective layer 22 is disposed on the protective layer 23. The protective layers 22 and 23 may together form the protective layer 24. The protective layer 24 is disposed on the second step surface 162 of the bottom electrode 16. That is, in this step, the protective layer 24 can be formed on the second step surface 162, the insulating layer 20 can be formed on the first step surface 161, and the top electrode 28 can be formed on the insulating layer 20. With the protective layer 24, it can prevent the etchant used in the etching process of defining the top electrode 28 from contacting the bottom electrode 16. Thereby, it can prevent the bottom electrode 16 from being damaged when defining the top electrode 28. For example, the second step surface 162 of the bottom electrode 16 can be prevented from becoming rough.

The material of the protective layer 23 can be a material which is more resistant to the aforementioned etchant. The material of the insulating layer 20 (also the material of the insulating layer 18 and the protective layer 22) and the material of the protective layer 23 preferably have a high etching selectivity ratio. Therefore, the process window for defining the top electrode 28 can be further enlarged. For example, the etching selectivity ratio of the material of the insulating layer 20 to the material of the protective layer 23 may be greater than or equal to 2.5. For example, the material of the insulating layer 20 may be silicon nitride (SiN), and the material of the protective layer 23 may be aluminum oxide (Al₂O₃), but not limited thereto.

Next, as shown in FIG. 12, a dielectric layer 32 may be blanketly deposited on the substrate 12 to cover the dielectric layer 30 and the protective layer 22. Next, the size of the bottom electrode 16 is defined, in which a portion of the dielectric layer 32, a portion of the protective layer 22, a portion of the protective layer 23, a portion of the bottom electrode 16 and a portion of the dielectric layer 14 are removed by semiconductor processes, such as one or more photolithography and etching processes. Next, a dielectric layer 34 is blanketly deposited on the substrate 12 to cover the dielectric layer 32 and the substrate 12.

Next, a first contact structure 42 electrically connected with the bottom electrode 16 and a second contact structure 44 electrically connected with the top electrode 28 may be formed, which may include steps as follows. The dielectric layer 36 may be blanketly deposited on the substrate 12 to cover the dielectric layer 34, and a portion of the dielectric layer 36 can be removed by a planarization process, so that the dielectric layer 36 has a flat top surface 361. Next, a plug process is performed to form the first contact structure 42 and the second contact structure 44 in the dielectric layer 36. The first contact structure 42 is electrically connected with the bottom electrode 16, and the second contact structure 44 is electrically connected with the top electrode 28. Thereby, the fabrication of the semiconductor device 10a can be completed. For other details for fabricating the semiconductor device 10a, references may be made to the related description of fabricating the semiconductor device 10.

Please refer to FIG. 12, which is a schematic cross-sectional view showing a semiconductor device 10a according to another embodiment of the present disclosure. The main difference between the semiconductor device 10a and the semiconductor device 10 is that the protective layer 24 is a composite structure formed by the protective layer 22 and protective layer 23. Specifically, the protective layer 24 includes a first sub-layer (i.e., the protective layer 22) and a second sub-layer (i.e., the protective layer 23) from top to bottom. The first sub-layer and the insulating layer 20 are formed in the same step, and the material of the first sub-layer is the same as the material of the insulating layer 20. The etching selectivity ratio of the material of the first sub-layer to the material of the second sub-layer may be greater than or equal to 2.5.

The first sub-layer (i.e., the protective layer 22) has a thickness T3, the protective layer 23 has a thickness T5, the protective layer 24 has a thickness T6, and the thickness T6 is equal to the sum of the thickness T3 and the thickness T5. The thickness T6 of the protective layer 24 is different from the thickness T41 of the insulating layer 20. According to an embodiment of the present disclosure, the ratio of the thickness T41 of the insulating layer 20 to the thickness T6 of the protective layer 24 may be greater than or equal to 4.

In this embodiment, the top surface 241 of the protective layer 24 (also the top surface 221 of the protective layer 22) is aligned with the first step surface 161, and the thickness T6 of the protective layer 24 is equal to the step difference SD2, but not limited thereto. In other embodiments, the top surface 241 of the protective layer 24 may be lower than the first step surface 161 (that is, the thickness T6 of the protective layer 24 may be less than the step difference SD2). In this embodiment, the length (not labeled) of the insulating layer 20 in the horizontal direction D1 is greater than the length (not labeled) of the first step surface 161 in the horizontal direction D1. There is a spacing distance HD (see FIG. 11) between the side surface 203 of the insulating layer 20 and the connecting surface 163 in the horizontal direction D1, and the protective layer 24 overlaps the insulating layer 20 in the vertical direction D2, but not limited thereto. In other embodiments, the side surface 203 of the insulating layer 20 may be aligned with the connecting surface 163. That is, the spacing distance HD is equal to 0. For other details of the semiconductor device 10a, references may be made to the relevant description of the semiconductor device 10, and are omitted herein.

Please refer to FIG. 14, which is a schematic cross-sectional view showing a semiconductor device 10b according to yet another embodiment of the present disclosure. The main difference between the semiconductor device 10b and the semiconductor device 10 is that the top surface 221 of the protective layer 22 may be lower than the first step surface 161. That is, the thickness T3 of the protective layer 22 is less than the step difference SD2. In addition, the length (not labeled) of the insulating layer 20 in the horizontal direction D1 may be equal to the length (not labeled) of the first step surface 161 in the horizontal direction D1. In this case, the side surface 203 of the insulating layer 20 is aligned with the connecting surface 163, a spacing distance HD (see FIG. 7) between the side surface 203 of the insulating layer 20 and the connecting surface 163 in the horizontal direction D1 is equal to 0, and the protective layer 22 does not overlap the insulating layer 20 in the vertical direction D2. For example, when defining the top electrode 28 (which may refer to the relevant description of FIG. 5), the coverage range of the etching mask (not shown) on the top electrode 28 may be adjusted, and the parameters of the etching process may be adjusted to control the etching depth, so that the semiconductor device 10b shown in FIG. 14 can be obtained. For other details of the semiconductor device 10b, references may be made to the relevant description of the semiconductor device 10, and are omitted herein.

Please refer to FIG. 15, which is a schematic cross-sectional view showing a semiconductor device 10c according to yet another embodiment of the present disclosure. The main difference between the semiconductor device 10c and the semiconductor device 10a is that the protective layer 24 is replaced by the protective layer 23. For example, in the steps shown in FIG. 8 or FIG. 13, the parameters of the deposition process may be controlled to adjust the thickness T5 of the protective layer 23, so that the top surface 231 of the protective layer 23 is aligned with the first step surface 161. That is, the thickness T5 of the protective layer 23 is equal to the step difference SD2. Compared with the protective layer 24 of the semiconductor device 10a, the protective layer 23 in this embodiment only includes a single film layer, and the material of the protective layer 23 is different from that of the insulating layer 20. For other details of the semiconductor device 10c, references may be made to the relevant description of the semiconductor device 10a, and are omitted herein.

Compared with the prior art, in the present disclosure, with the bottom electrode including the step structure, it can provide the space for disposing the protective layer. On the one hand, the capacitance value provided by the MIM structure is not affected. On the other hand, the process window of defining the top electrode can be enlarged. Thereby, the performance of the semiconductor device can be maintained and/or the yield of the semiconductor device can be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a bottom electrode comprising a first step structure, wherein the first step structure comprises a first step surface and a second step surface lower than the first step surface;
a protective layer disposed on the second step surface;
an insulating layer disposed on the first step surface;
a top electrode disposed on the insulating layer;
a first contact structure electrically connected with the bottom electrode; and
a second contact structure electrically connected with the top electrode.

2. The semiconductor device of claim 1, wherein a thickness of the protective layer is different from a thickness of the insulating layer.

3. The semiconductor device of claim 1, wherein a top surface of the protective layer is lower than or aligned with the first step surface.

4. The semiconductor device of claim 1, wherein the protective layer and the insulating layer comprises a same material.

5. The semiconductor device of claim 1, wherein an etching selectivity ratio of a material of the insulating layer to a material of the protective layer is greater than or equal to 2.5.

6. The semiconductor device of claim 1, wherein the protective layer comprises a first sub-layer and a second sub-layer from top to bottom, and a material of the first sub-layer is the same as a material of the insulating layer.

7. The semiconductor device of claim 6, wherein an etching selectivity ratio of a material of the first sub-layer to a material of the second sub-layer is greater than or equal to 2.5.

8. The semiconductor device of claim 1, wherein a ratio of a thickness of the insulating layer to a thickness of the protective layer is greater than or equal to 4.

9. The semiconductor device of claim 1, further comprising:
a dielectric layer disposed below the bottom electrode, wherein the dielectric layer comprises a second step structure, the second step structure comprises a third step surface and a fourth step surface lower than the third step surface, the first step surface is disposed above the third step surface, and the second step surface is disposed above the fourth step surface.

10. The semiconductor device of claim 9, wherein the dielectric layer has different thicknesses.

11. A method for fabricating a semiconductor device, comprising:
forming a bottom electrode, wherein the bottom electrode comprises a first step structure, and the first step structure comprises a first step surface and a second step surface lower than the first step surface;
forming a protective layer on the second step surface;
forming an insulating layer on the first step surface;
forming a top electrode on the insulating layer;
forming a first contact structure electrically connected with the bottom electrode; and
forming a second contact structure electrically connected with the top electrode.

12. The method of claim 11, wherein a thickness of the protective layer is different from a thickness of the insulating layer.

13. The method of claim 11, wherein a top surface of the protective layer is lower than or aligned with the first step surface.

14. The method of claim 11, wherein the protective layer and the insulating layer comprises a same material.

15. The method of claim 11, wherein an etching selectivity ratio of a material of the insulating layer to a material of the protective layer is greater than or equal to 2.5.

16. The method of claim 11, wherein the protective layer comprises a first sub-layer and a second sub-layer from top to bottom, and a material of the first sub-layer is the same as a material of the insulating layer.

17. The method of claim 16, wherein an etching selectivity ratio of a material of the first sub-layer to a material of the second sub-layer is greater than or equal to 2.5.

18. The method of claim 11, wherein a ratio of a thickness of the insulating layer to a thickness of the protective layer is greater than or equal to 4.

19. The method of claim 11, further comprising:
forming a dielectric layer, wherein the dielectric layer comprises a second step structure, the second step structure comprises a third step surface and a fourth step surface lower than the third step surface; and
forming the bottom electrode on the dielectric layer, wherein the first step surface is disposed above the third step surface, and the second step surface is disposed above the fourth step surface.

20. The method of claim 19, wherein the dielectric layer has different thicknesses.
